(19) United States
(12) Patent Application Publication
(10) Pub. No.: US 2026/0161354 A1
(43) Pub. Date: Jun. 11, 2026

(54) SYSTEM, CIRCUIT AND METHOD FOR DATA PROCESSING

(71) Applicant: TAIWAN SEMICONDUCTOR MANUFACTURING COMPANY, LTD., Hsinchu (TW)

(72) Inventors: Win-San KHWA, Taipei City (TW); Ping-Sheng WU, Hsinchu City (TW); Meng-Fan CHANG, Taichung City (TW)

(73) Assignee: TAIWAN SEMICONDUCTOR MANUFACTURING COMPANY, LTD., Hsinchu (TW)

(21) Appl. No.: 18/970,045

(22) Filed: Dec. 5, 2024

(51) Int. Cl. G06F 7/485; G06F 5/01; G06F 7/02; H03K 19/20

(52) U.S. Cl. CPC G06F 7/485; G06F 5/012; G06F 7/02; H03K 19/20

(57) ABSTRACT

A system comprising an artificial intelligence accelerator circuit and a data processing circuit is provided. The data processing circuit receives a first input and a second input from the artificial intelligence accelerator circuit and performs an addition between the first and second inputs to generate a sum. The data processing circuit comprises an input processing circuit, an exponent circuit, a mantissa circuit. The input processing circuit extracts a first sign, a first mantissa and a first exponent from the first input. The exponent circuit performs a mantissa alignment to generate first and second aligned mantissas and a maximum exponent. The mantissa circuit performs an addition or a subtraction between the first and second aligned mantissas to generate a third sign, a third exponent and a third mantissa according to the first and second signs and the maximum exponent.

### BACKGROUND

In some application like artificial intelligence accelerator for edge computing, support for computation of different datatypes are usually required. Some approaches use dedicated hardware for each datatype, resulting in large area overhead. A design of hardware reuse for different datatypes helps improve the area performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a system in accordance with various embodiments of the present disclosure.

FIG. 2 is a schematic diagram of a system configured with respect to the system in FIG. 1, in accordance with various embodiments of the present disclosure.

FIG. 3 is a schematic diagram of a data processing circuit, in accordance with various embodiments of the present disclosure.

FIG. 4 is a schematic diagram of an example of the input processing circuit of the data processing circuit in FIG. 3, in accordance with various embodiments of the present disclosure.

FIG. 5 is a schematic diagram of an example of the input processing circuit and the special case handling circuit of the data processing circuit in FIG. 3, in accordance with various embodiments of the present disclosure.

FIG. 6 is a schematic diagram of an example of the input processing circuit and the exponent circuit of the data processing circuit in FIG. 3, in accordance with various embodiments of the present disclosure.

FIG. 7 is a schematic diagram of an example of the input processing circuit, the exponent circuit and the mantissa circuit of the data processing circuit in FIG. 3, in accordance with various embodiments of the present disclosure.

FIG. 8 is a schematic diagram of an example of the special case handling circuit, the mantissa circuit and the output processing circuit of the data processing circuit in FIG. 3, in accordance with various embodiments of the present disclosure.

FIG. 9 is a schematic diagram of a input processing circuit configured with respect to the input processing circuit in FIG. 4, in accordance with various embodiments of the present disclosure.

FIG. 10 is a schematic diagram of an example of the exponent align circuit of the data processing circuit in FIG. 9, in accordance with various embodiments of the present disclosure.

FIG. 11 is a schematic diagram of an output processing circuit configured with respect to the output processing circuit in FIG. 8, in accordance with various embodiments of the present disclosure.

FIG. 12 is a flowchart diagram of a method for operating the system and the data processing circuit as shown in FIGS. 1-11, in accordance with some embodiments of the present disclosure.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

As used herein, “around”, “about”, “approximately” or “substantially” shall generally refer to any approximate value of a given value or range, in which it is varied depending on various arts in which it pertains, and the scope of which should be accorded with the broadest interpretation understood by the person skilled in the art to which it pertains, so as to encompass all such modifications and similar structures. In some embodiments, it shall generally mean within 20 percent, preferably within 10 percent, and more preferably within 5 percent of a given value or range. Numerical quantities given herein are approximate, meaning that the term “around”, “about”, “approximately” or “substantially” can be inferred if not expressly stated, or meaning other approximate values.

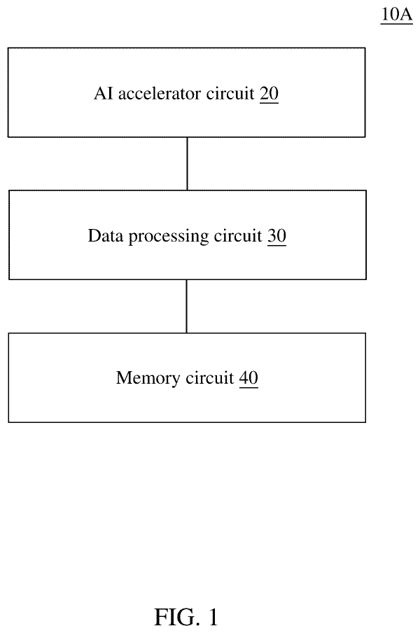

Reference is now made to FIG. 1. FIG. 1 is a schematic diagram of a system 10A in accordance with various embodiments of the present disclosure. In some embodiments, the system 10A is an artificial intelligence (AI) accelerator system. For illustration, the system 10A includes an AI accelerator circuit 20, a data processing circuit 30 and a memory circuit 40. The AI accelerator circuit 20 is coupled to the data processing circuit 30. The data processing circuit 30 is coupled to the memory circuit 40.

In some embodiments, the AI accelerator circuit 20 is configured to perform computations of a machine learning model (e.g., neural network model). In some embodiments, the AI accelerator circuit 20 is a computing-in-memory (CIM) system. In some embodiments, the AI accelerator circuit 20 is a near-memory-computing (NMC) system.

For practical applications, the machine learning model of the AI accelerator circuit 20 may be utilized in various fields such as machine vision, image classification, or data classification. For example, the machine learning model may be used for classifying medical images. For example, it can be used to classify X-ray images in normal conditions, with pneumonia, with bronchitis, or with heart disease. The machine learning model may also be used to classify ultrasound images with normal fetuses or abnormal fetal positions. On the other hand, the machine learning model can also be used to classify images collected in automatic driving, such as distinguishing normal roads, roads with obstacles, and road conditions images of other vehicles. Furthermore, the machine learning model can be utilized in other similar fields, such like music spectrum recognition, spectral recognition, big data analysis, data feature recognition and other related machine learning fields.

In some embodiments, the data processing circuit 30 is configured to perform data processing of the data from the AI accelerator circuit 20. For example, the data processing circuit 30 receives data corresponding to computation results of the machine learning model from the AI accelerator circuit 20. Then, the data processing circuit 30 performs data processing to the received data to generate processed data. The memory circuit 40 receives the processed data from the data processing circuit 30 and stores the processed data.

According to various embodiments, the memory circuit 40 may include any suitable memory, for example, a static random-access memory (SRAM), a resistive random-access memory (ReRAM), a gain cell memory, etc.

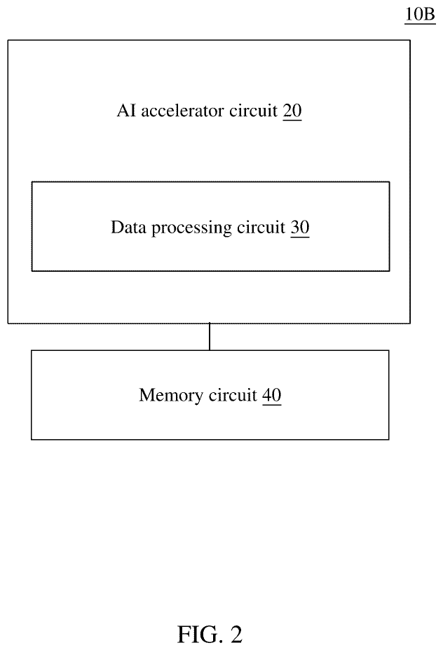

Reference is now made to FIG. 2. FIG. 2 is a schematic diagram of a system 10B configured with respect to the system 10A in FIG. 1, in accordance with various embodiments of the present disclosure. With respect to the embodiments of FIG. 1, like elements in FIG. 2 are designated with the same reference numbers for ease of understanding. The specific operations of similar elements, which are already discussed in detail previously, are omitted for the sake of brevity.

The difference between the system 10A and the system 10B is that in the system 10B, the data processing circuit 30 is included in the AI accelerator circuit 20.

In some embodiments, the data processing circuit 30 performs data processing to computation results of the AI accelerator circuit 20 to generate processed data. For example, the data processing circuit 30 performs addition to the computation results. In some embodiments, the AI accelerator circuit 20 performs further computations (e.g., accumulation) to the processed data and outputs the results to the memory circuit 40.

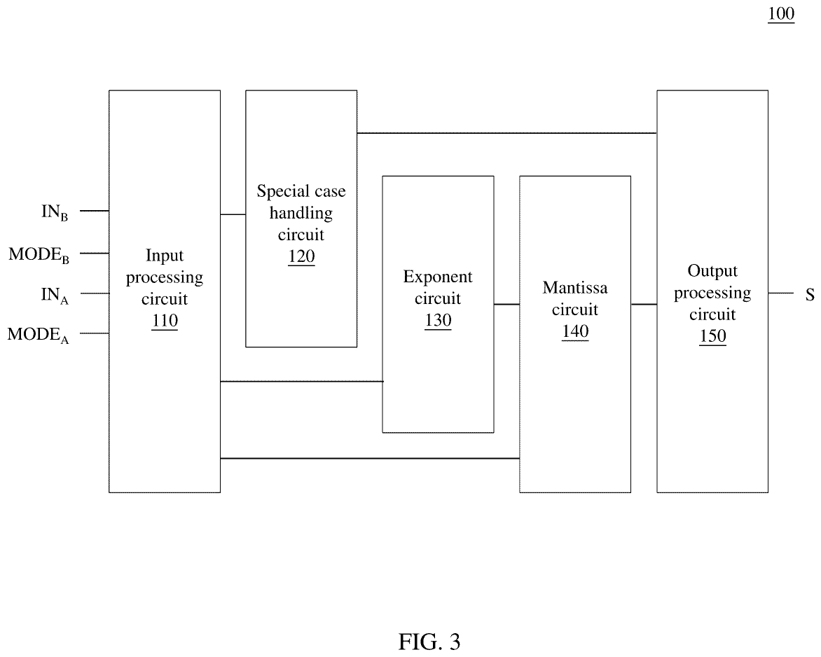

Reference is now made to FIG. 3. FIG. 3 is a schematic diagram of a data processing circuit 100, in accordance with various embodiments of the present disclosure. In some embodiments, the data processing circuit 30 corresponding to the system 10A and 10B includes the data processing circuit 100. In some embodiments, the data processing circuit 100 is an integrated circuit.

In some embodiments, the data processing circuit 100 receives an input IN_{A} and an input IN_{B}. In some embodiments, the input IN_{A} and an input IN_{B} are from the AI accelerator circuit 20. In some embodiments, the data processing circuit 100 is an addition circuit. The data processing circuit 100 performs addition between the input IN_{A} and IN_{B} to generate a sum S. In some embodiments, the data processing circuit 100 outputs the sum S as the processed data.

In some embodiments, the inputs IN_{A} and IN_{B} may have different data type. For example, the input IN_{A} may be an integer and the input IN_{B} may be a floating point number. The data processing circuit 100 processes the inputs IN_{A} and IN_{B} that have different data type to perform addition therebetween.

In some embodiments, the data processing circuit 100 further receives data MODE_{A} and MODE_{B} corresponding to the inputs IN_{A} and IN_{B} respectively. The data MODE_{A} and MODE_{B} indicate the data type of the inputs IN_{A} and IN_{B}. The data processing circuit 100 processes the inputs IN_{A} and IN_{B} according to the data MODE_{A} and MODE_{B}.

For illustration, the data processing circuit 100 includes an input processing circuit 110, a special case handling circuit 120, an exponent circuit 130, a mantissa circuit 140 and an output processing circuit 150. The input processing circuit 110 is coupled to the special case handling circuit 120, the exponent circuit 130 and the mantissa circuit 140. The special case handling circuit 120 is coupled to the output processing circuit 150. The exponent circuit 130 is coupled to the mantissa circuit 140. The mantissa circuit 140 is coupled to the output processing circuit 150.

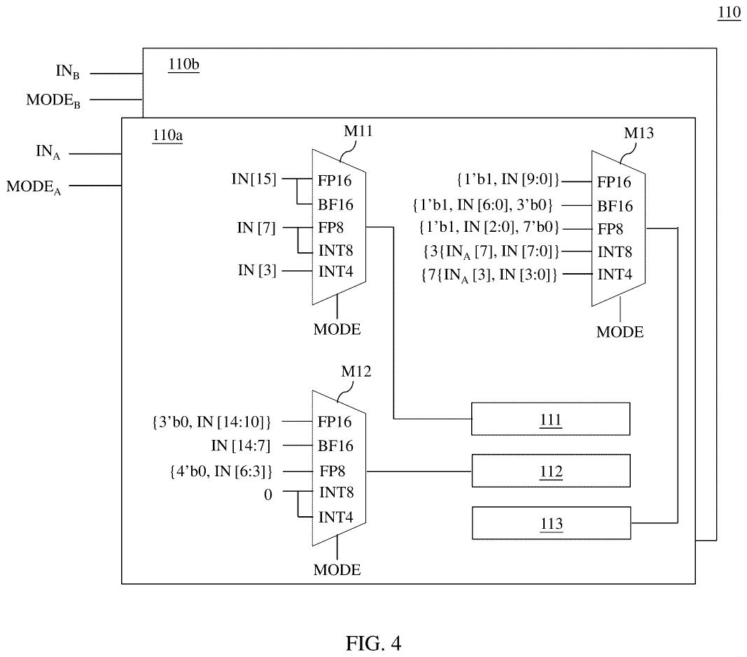

Further configurations and operations of the input processing circuit 110, the special case handling circuit 120, the exponent circuit 130, the mantissa circuit 140 and the output processing circuit 150 are described in the following paragraphs with reference to FIGS. 4-9.

Reference is now made to FIG. 4. FIG. 4 is a schematic diagram of an example of the input processing circuit 110 of the data processing circuit 100 in FIG. 3, in accordance with various embodiments of the present disclosure. With respect to the embodiments of FIGS. 1-3, like elements in FIG. 4 are designated with the same reference numbers for ease of understanding.

For illustration, the input processing circuit 110 includes a processing circuit 110a and a processing circuit 110b. The processing circuit 110a receives the input IN_{A} and the data MODE_{A} and processes the input IN_{A} and the data MODE_{A}. The processing circuit 110b receives the input IN_{B} and the data MODE_{B} and processes the input IN_{B} and the data MODE_{B}.

For example, in a case of the data processing circuit 100 performing an addition between decimal values of “320” and “96” in datatype of 16-bit floating point (FP16) and 8-bit floating point (FP8) respectively, the input IN_{A} may be a FP16 number 16′b0101110100000000 corresponding to the decimal value of “320” and the input IN_{B} may be a FP8 number 8′b01101100 corresponding to the decimal value of “96”. In this case, the data MODE_{A} and MODE_{B} would be configured to indicate FP16 and FP8 respectively. It is noted that, throughout the specification, “n′b” indicates “n” bits, in which “n” is a integer. For example, 8′b01101100 refers to 8 bits of “01101100”.

As shown in FIG. 4, each of the processing circuits 110a and 110b includes a multiplexer M11, multiplexer M12, multiplexer M13, a register 111, a register 112 and a register 113. The multiplexer M11, multiplexer M12, multiplexer M13, register 111, register 112 and register 113 of the processing circuits 110a and 110b have similar configurations.

For illustration, the multiplexer M11 is coupled to the register 111. The multiplexer M12 is coupled to the register 112. The multiplexer M13 is coupled to the register 113.

The registers 111, 112 and 113 are configured to store the sign, the exponent and the mantissa of data with different datatypes. In some embodiments, the capacity (bit lengths) of the registers 111, 112 and 113 are according to the maximum bit lengths of the sign, the exponent and the mantissa among different datatypes.

For example, the exponent of brain floating point (BF16) has the longest bit length (8 bits) among exponents of different datatypes. The register 112 is configured to have a bit length of 8 bits. The mantissa of 16-bit floating point (FP16) has the longest bit length (11 bits) among mantissas of different datatypes. The register 113 is configured to have a bit length of 11 bits. The register 111 is configured to have a bit length of one bit since the signs of different datatypes are one bit.

The multiplexer M11 is configured to generate a sign of an input IN according to data MODE and the register 111 stores the sign from the multiplexer M11. It should be noted that in the processing circuits 110a, the input IN is the input IN_{A} and the data MODE is the data MODE_{A}. In the processing circuits 110b, the input IN is the input IN_{B} and the data MODE is the data MODE_{B}.

The multiplexer M11 is configured to extract the sign bit from the input IN according to the data MODE and output the sign bit as the sign to the register 111.

Specifically, when the MODE is 16-bit floating point (FP16) or brain floating point (BF16), the multiplexer M11 selects data IN[15] and output the data IN[15] as the sign to the register 111.

It should be noted that the annotation of brackets with index number inside denotes a bit or bits in corresponding data. The index number denotes an index starting from a least significant bit (LSB). For example, the data IN[15] corresponds to the sixteenth bit starting from the LSB in the input IN. The data IN[15] corresponds to the sign bit of the FP16 and BF16.

Similarly, when the MODE is 8-bit floating point (FP8) or 8-bit integer (INT8), the multiplexer M11 selects data IN[7] and output the data IN[7] as the sign to the register 111. The data IN[7] corresponds to the eighth bit starting from the LSB in the input IN. The data IN[7] corresponds to the sign bit of the FP8 and INT8.

When the MODE is 4-bit integer (INT4), the multiplexer M11 selects data IN[3] and output the data IN[3] as the sign to the register 111. The data IN[3] corresponds to the fourth bit starting from the LSB in the input IN. The data IN[3] corresponds to the sign bit of the INT4.

Take the input IN_{A} being the FP16 number 16′b0101110100000000 (“320” in decimal form) and the input IN_{B} being the FP8 number 8′b01101100 (“96” in decimal form) for example. The multiplexer M11 of the processing circuit 110a extracts the sign bit 1′b0 (IN[15]) from the input IN_{A} and the multiplexer M11 of the processing circuit 110b extracts the sign bit 1′b0 (IN[7]) from the input IN_{B} to output.

The multiplexer M12 is configured to retrieve the exponent bits from the input IN according to the data MODE and output the exponent bits as an exponent to the register 112. The register 112 stores the exponent from the multiplexer M12.

Specifically, when the MODE is FP16, the multiplexer M12 selects data {3′b0, IN[14:10]} and output the data {3′b0, IN[14:10]} as the exponent to the register 112. The data IN[14:10] corresponds to the eleventh to fifth bits in the input IN. The data IN[14:10] corresponds to exponent bits of the FP16. The processing circuit 110a or 110b pads the data IN[14:10] with three bits of zero (3′b0) from the most significant bit (MSB) side to generate the data {3′b0, IN[14:10]}.

When the MODE is BF16, the multiplexer M12 selects data IN[14:7] and output the data IN[14:7] as the exponent to the register 112. The data IN[14:7] corresponds to exponent bits of the BF16.

When the MODE is FP8, the multiplexer M12 selects data {4′b0, IN[6:3]} and output the data {4′b0, IN[6:3]} as the exponent to the register 112. The data IN[6:3] corresponds to exponent bits of the FP8. The processing circuit 110a or 110b pads the data IN[6:3] with four bits of zero (4′b0) from the most significant bit (MSB) side to generate the data {4′b0, IN[6:3]}.

When the MODE is INT8 or INT4, the multiplexer M12 selects data 0 and output the data 0 as the exponent to the register 112. In some embodiments, the data 0 is eight bits of zero (8′b0).

Take the input IN_{A} being the FP16 number 16′b0101110100000000 (“320” in decimal form) and the input IN_{B} being the FP8 number 8′b01101100 (“96” in decimal form) for example. The multiplexer M12 of the processing circuit 110a outputs the data {3′b0, IN[14:10]} corresponding to the input IN_{A} according to the data MODE being FP16.

In this case, the data IN[14:10] (the exponent bits of FP16) of the input IN_{A} would be bits 5′b10111 and the data {3′b0, IN[14:10]} of the input IN_{A} would be bits 8′b00010111. The multiplexer M12 of the processing circuit 110a outputs the bits 8′b00010111 indicating the exponent of the input IN_{A}.

Similarly, The multiplexer M12 of the processing circuit 110b outputs the data {4′b0, IN[6:3]} corresponding to the input IN_{B} according to the data MODE being FP8.

In this case, the data IN[6:3] (the exponent bits of FP8) of the input IN_{B} would be bits 4′b1101 and the data {4′b0, IN[6:3]} of the input IN_{B} would be 8′b00001101. The multiplexer M12 of the processing circuit 110b outputs 8′b00001101 indicating the exponent of the input IN_{B}.

As described above, the processing circuits 110a and 110b pad the exponent bits of the input IN to have a fix bit length (e.g., 8 bits). In some embodiments, the fix bit length is equal to the bit length of the exponent bits of a data type that have the longest exponent bits. For example, among the data types FP16, BF16, FP8, INT8 and INT4, the BF16 has the longest exponent bits (8 bits). The processing circuits 110a and 110b pad exponent of the input IN to have 8 bits. Then, the multiplexer M12 outputs the padded exponent.

The multiplexer M13 is configured to retrieve the mantissa bits from the input IN according to the data MODE and output the mantissa bits as a mantissa to the register 113. The register 113 stores the mantissa from the multiplexer M13.

Specifically, when the MODE is FP16, the multiplexer M12 selects data {1′b1, IN[9:0]} and output the data {1′b1, IN[9:0]} as the mantissa to the register 113. The data IN[9:0] corresponds to mantissa bits of the FP16. The processing circuit 110a or 110b pads the data IN[14:10] with one bits of one (1′b1) from the most significant bit (MSB) side to generate the data {1′b1, IN[9:0]}.

When the MODE is BF16, the multiplexer M12 selects data {1′b1, IN[6:0], 3′b0} and output the data {1′b1, IN[6:0], 3′b0} as the mantissa to the register 113. The data IN[6:0] corresponds to mantissa bits of the BF16. The processing circuit 110a or 110b pads the data IN[14:10] with one bits of one (1′b1) from the MSB side and three bits of zero (3′b0) from the LSB side to generate the data {1′b1, IN[6:0], 3′b0}.

When the MODE is FP16, the multiplexer M12 selects data {1′b1, IN[2:0], 7′b0} and output the data {1′b1, IN[2:0], 7′b0} as the mantissa to the register 113. The data IN[2:0] corresponds to mantissa bits of the FP16. The processing circuit 110a or 110b pads the data IN[2:10] with one bits of one (1′b1) from the MSB side and seven bits of zero (7′b0) from the LSB side to generate the data {1′b1, IN[2:0], 7′b0}.

When the MODE is INT8, the multiplexer M12 selects data {3{INT [7]}, IN[7:0]} and output the data {3{IN[7]}, IN[7:0]} as the mantissa to the register 113. The data IN[7] corresponds to the sign bit of the INT8. Different from the input IN of floating point, a sign extension is performed to the input IN of integer. For example, the processing circuit 110a or 110b pads the data IN[7:0] with three bits of data IN[7] (3{IN[7]}) from the MSB side to generate the data {3{IN[7]}, IN[7:0]}, in which the padding of sign bits is referred to as the sign extension.

When the MODE is INT4, the multiplexer M12 selects data {{INT [3]}, IN[3:0]} and output the data {7{IN[3]}, IN[3:0]} as the mantissa to the register 113. The data IN[3] corresponds to the sign bit of the INT4. The processing circuit 110a or 110b pads the data IN[3:0] with seven bits of data IN[3] (7{IN[3]}) from the MSB side to generate the data {7{IN[3]}, IN[3:0]}.

Take the input IN_{A} being the FP16 number 16′b0101110100000000 (“320” in decimal form) and the input IN_{B} being the FP8 number 8′b01101100 (“96” in decimal form) for example. The multiplexer M13 of the processing circuit 110a outputs the data {1′b1, IN[9:0]} corresponding to the input IN_{A} according to the data MODE being FP16.

In this case, the data IN[9:0] (the mantissa bits of FP16) of the input IN_{A} would be bits 10′b0100000000 and the data {1′b1, IN[9:0]} of the input IN_{A} would be bits 11′b10100000000. The multiplexer M12 of the processing circuit 110a outputs the bits 11′b10100000000 indicating the mantissa of the input IN_{A}.

Similarly, The multiplexer M13 of the processing circuit 110b outputs the data {1′b1, IN[2:0], 7′b0} corresponding to the input IN_{B} according to the data MODE being FP8.

In this case, the data IN[2:0] (the mantissa bits of FP8) of the input IN_{B} would be bits 3′b100 and the data {1′b1, IN[2:0], 7′b0} of the input IN_{B} would be bits 11′b11000000000. The multiplexer M12 of the processing circuit 110b outputs the bits 11′b11000000000 indicating the mantissa of the input IN_{B}.

As described above, the processing circuits 110a and 110b pad the mantissa bits of the input IN to have a fix bit length (e.g., 11 bits). In some embodiments, the fix bit length is equal to the bit length of the mantissa bits of a data type that have the longest exponent bits plus one bit. For example, among the data types FP16, BF16, FP8, INT8 and INT4, the FP16 has the longest mantissa bits (10 bits). The processing circuits 110a and 110b pad mantissa of the input IN to have 11 bits. Then, the multiplexer M12 outputs the padded mantissa.

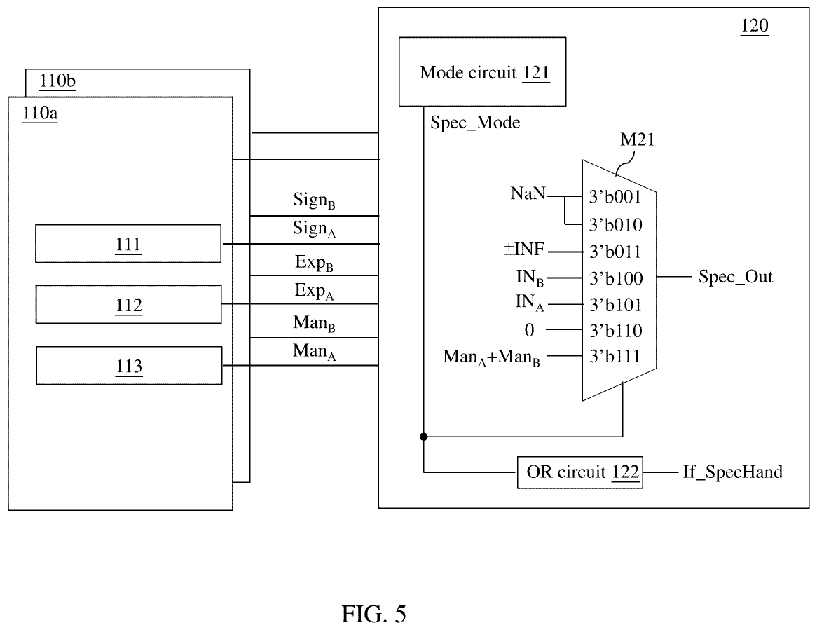

Reference is now made to FIG. 5. FIG. 5 is a schematic diagram of an example of the input processing circuit 110 and the special case handling circuit 120 of the data processing circuit 100 in FIG. 3, in accordance with various embodiments of the present disclosure. With respect to the embodiments of FIGS. 1-4, like elements in FIG. 5 are designated with the same reference numbers for ease of understanding.

For illustration, the special case handling circuit 120 includes a multiplexer M21, a mode circuit 121 and an OR circuit 122. In some embodiments, the registers 111, 112 and 113 of the processing circuit 110a and 110b are coupled to the special case handling circuit 120. The registers 111, 112 and 113 of the processing circuit 110a output the sign Sign_{A}, the exponent Exp_{A}, the mantissa Man_{A} stored therein to the special case handling circuit 120. Similarly, the registers 111, 112 and 113 of the processing circuit 110b output the sign Sign_{B}, the exponent Exp_{B}, the mantissa Man_{B} stored therein to the special case handling circuit 120.

The mode circuit 121 determines data Spec_Mode according to the inputs IN_{A} and IN_{B} (or the sign Sign_{A}, the exponent Exp_{A}, the mantissa Man_{A}, the sign Sign_{B}, the exponent Exp_{B} and the mantissa Man_{B}) and the data MODE_{A} and MODE_{B}. The data Spec_Mode indicates which special case the inputs IN_{A} and IN_{B} belong to. For example, the inputs IN_{A} and IN_{B} may belong to a special case of being not a number (NaN).

The mode circuit 121 determines the data Spec_Mode through the following statement: if IN_{A}==NaN or IN_{B}==NaN: Spec_Mode=3′b001; else if IN_{A}==−IN_{B}==INF or −IN_{A}==IN_{B}==INF: Spec_Mode=3′b010; else if IN_{A}==+INF or IN_{B}==+INF: Spec_Mode=3′b011; else if IN_{A}==+INF or IN_{B}==+INF: Spec_Mode=3′b011; else if IN_{A}==0: Spec_Mode=3′b100; else if IN_{B}==0: Spec_Mode=3′b101; else if IN_{A}==−IN_{B}: Spec_Mode=3′b110; else if MODE_{A,B}==INT4 or INT8: Spec_Mode=3′b111; else: Spec_Mode=3′b000.

Specifically, when the input the inputs IN_{A} or IN_{B} is NaN, the data Spec_Mode is determined to be three bits “001” (3′b001).

When the inputs IN_{A} and IN_{B} are not in the above condition, the sign of the input IN_{A} and the sign of the input IN_{B} are inverted to each other and one of the inputs IN_{A} and IN_{B} is infinity (INF), the Spec_Mode is determined to be three bits “010” (3′b010).

When the inputs IN_{A} and IN_{B} are not in the above conditions and one of the inputs IN_{A} and IN_{B} is infinity (INF) or negative infinity (−INF), the data Spec_Mode is determined to be three bits “011” (3′b011).

When the inputs IN_{A} and IN_{B} are not in the above conditions and the input IN_{A} is equal to zero, the data Spec_Mode is determined to be three bits “100” (3′b100).

When the inputs IN_{A} and IN_{B} are not in the above conditions and the input IN_{B} is equal to zero, the data Spec_Mode is determined to be three bits “100” (3′b101).

When the inputs IN_{A} and IN_{B} are not in the above conditions and the inputs IN_{A} and IN_{B} are inverted to each other, the data Spec_Mode is determined to be three bits “100” (3′b110).

When the inputs IN_{A} and IN_{B} are not in the above conditions and the inputs IN_{A} and IN_{B} are integers (the data MODE_{A} are INT4 or INT8 and the data MODE_{B} are INT4 or INT8), the data Spec_Mode is determined to be three bits “100” (3′b111).

When the inputs IN_{A} and IN_{B} are not in the above conditions, the data Spec_Mode is determined to be a default that is three bits “000” (3′b000).

In some embodiments, the above determination is according to the sign Sign_{A}, the exponent Exp_{A}, the mantissa Man_{A}, the sign Sign_{B}, the exponent Exp_{B} and the mantissa Man. For example, the mode circuit 121 determines whether inputs IN_{A} and IN_{B} are equal to each other by comparing the sign Sign_{A}, the exponent Exp_{A}, the mantissa Man_{A} with the sign Sign_{B}, the exponent Exp_{B}, the mantissa Man_{B}.

The multiplexer M21 outputs data Spec_Out according to the data Spec_Mode. Specifically, when the Spec_Mode is 3′b001 or 3′b010, the multiplexer M21 selects NaN as the data Spec_Out to output. When the Spec_Mode is 3′b011, the multiplexer M21 selects ±INF as the data Spec_Out to output. When the Spec_Mode is 3′b100, the multiplexer M21 selects IN_{B} as the data Spec_Out to output. When the Spec_Mode is 3′b101, the multiplexer M21 selects IN_{A} as the data Spec_Out to output. When the Spec_Mode is 3′b110, the multiplexer M21 selects a number of zero as the data Spec_Out to output. When the Spec_Mode is 3′b111, the multiplexer M21 selects the mantissa Man_{A} plus the mantissa Man_{B} as the data Spec_Out to output.

The data Spec_Out indicates a special case that the inputs IN_{A} and IN_{B} belong to.

The OR circuit 122 is configured to generate data If_SpecHand according to the data Spec_Mode. The data If_SpecHand indicates whether the inputs IN_{A} and IN_{B} belong to a special case. For example, when the inputs IN_{A} and IN_{B} belong to a special case (i.e., the data Spec_Mode is equal to one of 3′b001, 3′b010. 3′b011, 3′b100, 3′b101, 3′b110, 3′b111), the OR circuit 122 generate a bit one as the data If_SpecHand. When the inputs IN_{A} and IN_{B} do not belong to a special case (i.e., the data Spec_Mode is equal to 3′b000), the OR circuit 122 generate a bit zero as the data If_SpecHand.

In some embodiments, the OR circuit 122 is a bit-wise OR circuit. Specifically, the OR circuit 122 performs OR operations to each bit of the data Spec_Mode to generate the data If_SpecHand. In some embodiments, the OR circuit 122 includes at least one OR gate.

Take the input IN_{A} being the FP16 number 16′b0101110100000000 (“320” in decimal form) and the input IN_{B} being the FP8 number 8′b01101100 (“96” in decimal form) for example. In this case, the inputs IN_{A} and IN_{B} do not belong to a special cases, the data Spec_Mode is 3′b000. The OR circuit 122 generates 1′b0 as the data If_SpecHand.

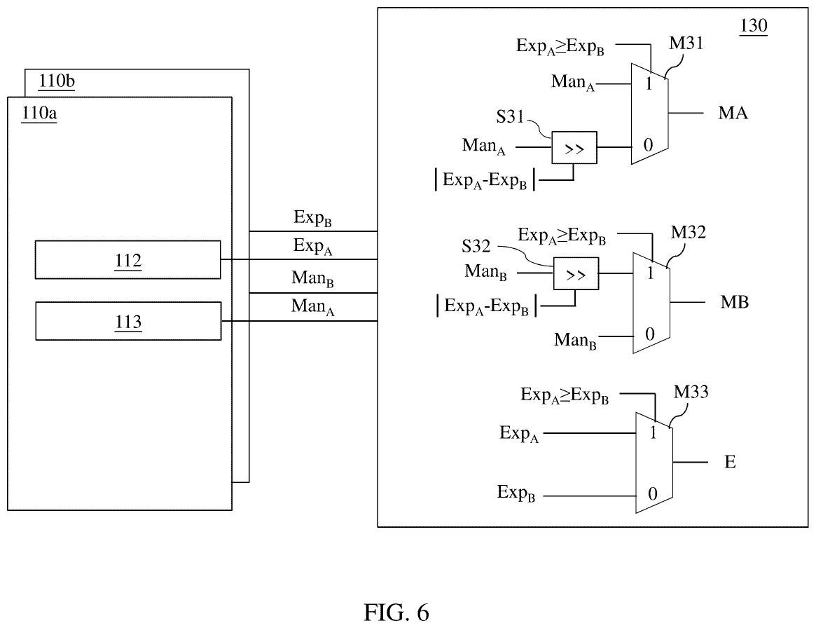

Reference is now made to FIG. 6. FIG. 6 is a schematic diagram of an example of the input processing circuit 110 and the exponent circuit 130 of the data processing circuit 100 in FIG. 3, in accordance with various embodiments of the present disclosure. With respect to the embodiments of FIGS. 1-5, like elements in FIG. 6 are designated with the same reference numbers for ease of understanding.

The exponent circuit 130 is configured to perform a comparison between the exponents Exp_{A} and Exp_{B} to find a maximum. The exponent circuit 130 determines the maximum as an exponent E to output. The exponent circuit 130 further performs mantissa alignment to the mantissas Man_{A} and Man_{B} to generate aligned mantissas MA and MB according to the comparison.

For illustration, the registers 112 and 113 are coupled to the exponent circuit 130. The registers 112 and 113 of the processing circuit 110a outputs the exponent Exp_{A} and the mantissa Man_{A} to the exponent circuit 130 respectively. Similarly, the registers 112 and 113 of the processing circuit 110b outputs the exponent Exp_{B} and the mantissa Man_{B} to the exponent circuit 130 respectively.

As shown in FIG. 6, the exponent circuit 130 includes a multiplexer M31, a multiplexer M32, a multiplexer M33, a shifter circuit S31 and a shifter circuit S32. An input terminal of the multiplexer M31 is coupled to the shifter circuit S31. An input terminal of the multiplexer M32 is coupled to the shifter circuit S32.

The multiplexer M31 is configured to output the mantissa MA according to the exponents Exp_{A}, Exp_{B} and the mantissa Man_{A}. Specifically, the exponent circuit 130 determines whether the exponent Exp_{A} is greater than or equal to the exponent Exp_{B}. When the exponent circuit 130 determines that the exponent Exp_{A} is greater than or equal to the exponent Exp_{B}, the exponent circuit 130 output a control signal of a bit one to the multiplexer M31. When the exponent circuit 130 determines that the exponent Exp_{A} is smaller than the exponent Exp_{B}, the exponent circuit 130 output a control signal of a bit zero to the multiplexer M31.

When the control signal received by the multiplexer M31 is a bit one, the multiplexer M31 selects the mantissa Man_{A} as the mantissa MA to output.

The exponent circuit 130 generate the absolute value of the exponent Exp_{A} minus the exponent Exp_{B} (|Exp_{A}−Exp_{B}|). The shifter circuit S31 shifts the bits of the mantissa Man_{A} to the right (the LSB side) by a bit number of the absolute value. For example, when the absolute value |Exp_{A}−Exp_{B}| is one, the shifter circuit S31 shifts the bits of the mantissa Man_{A} to the right by one bit. In some embodiments, the shifter circuit S31 pads zero to the shifted mantissa Man_{A} to maintain the bit length.

When the control signal received by the multiplexer M31 is a bit zero, the multiplexer M31 selects the shifted mantissa Man_{A} from the shifter circuit S31 as the mantissa MA to output.

The multiplexer M32 is configured to output the mantissa MB according to the exponents Exp_{A}, Exp_{B} and the mantissa Man_{B}. Specifically, the exponent circuit 130 determines whether the exponent Exp_{A} is greater than or equal to the exponent Exp_{B}. When the exponent circuit 130 determines that the exponent Exp_{A} is greater than or equal to the exponent Exp_{B}, the exponent circuit 130 output a control signal of a bit one to the multiplexer M32. When the exponent circuit 130 determines that the exponent Exp_{A} is smaller than the exponent Exp_{B}, the exponent circuit 130 output a control signal of a bit zero to the multiplexer M32.

The shifter circuit S32 shifts the bits of the mantissa Man_{B} to the right (the LSB side) by the bit number of the absolute value |Exp_{A}−Exp_{B}|. In some embodiments, the shifter circuit S32 pads zero to the shifted mantissa Man_{B} to maintain the bit length.

When the control signal received by the multiplexer M32 is a bit one, the multiplexer M32 selects the shifted mantissa Man_{B} from the shifter circuit S32 as the mantissa MB to output.

When the control signal received by the multiplexer M32 is a bit zero, the multiplexer M32 selects the mantissa Man_{B} as the mantissa MB to output.

Take the input IN_{A} being the FP16 number 16′b0101110100000000 (“320” in decimal form) and the input IN_{B} being the FP8 number 8′b01101100 (“96” in decimal form) for example. In this case, the exponents Exp_{A} and Exp_{B} are 8′b00010111 and 8′b00001101 respectively. The mantissas Man_{A} and Man_{B} are 11′b10100000000 and 11′b11000000000 respectively.

According to the exponent Exp_{A} being greater than the exponent Exp_{B}, the multiplexer M31 outputs the mantissa Man_{A} (11′b10100000000) as the aligned mantissa MA.

The shifter circuit S32 shifts the bits of the mantissa Man_{B} to the right (the LSB side) by a number of ten which is the value of | Exp_{A}−Exp_{B}| and the shifter circuit S32 generates the shifted mantissa Man_{B} which is 11′b00000000001. Then, according to the exponent Exp_{A} being greater than the exponent Exp_{B}, the multiplexer M32 outputs the the shifted mantissa Man_{B} (11′b00000000001) as the aligned mantissa MB.

The multiplexer M33 is configured to output an exponent E according to the exponents Exp_{A} and Exp_{B}. In some embodiments, the exponent circuit 130 determines the greater one of the exponents Exp_{A} and Exp_{B} to be the exponent E to output.

Specifically, the exponent circuit 130 determines whether the exponent Exp_{A} is greater than or equal to the exponent Exp_{B}. When the exponent circuit 130 determines that the exponent Exp_{A} is greater than or equal to the exponent Exp_{B}, the exponent circuit 130 output a control signal of a bit one to the multiplexer M33. When the exponent circuit 130 determines that the exponent Exp_{A} is smaller than the exponent Exp_{B}, the exponent circuit 130 output a control signal of a bit zero to the multiplexer M33.

When the control signal received by the multiplexer M33 is a bit one, the multiplexer M33 selects the exponent Exp_{A} as the exponent E to output.

When the control signal received by the multiplexer M33 is a bit zero, the multiplexer M33 selects the exponent Exp_{B} as the exponent E to output.

Take the input IN_{A} being the FP16 number 16′b0101110100000000 (“320” in decimal form) and the input IN_{B} being the FP8 number 8′b01101100 (“96” in decimal form) for example. As described above, in this case, the exponents Exp_{A} and Exp_{B} are 8′b00010111 and 8′b00001101 respectively. According to the exponent Exp_{A} being greater than the exponent Exp_{B}, the multiplexer M33 outputs the exponent Exp_{A} as the exponent E.

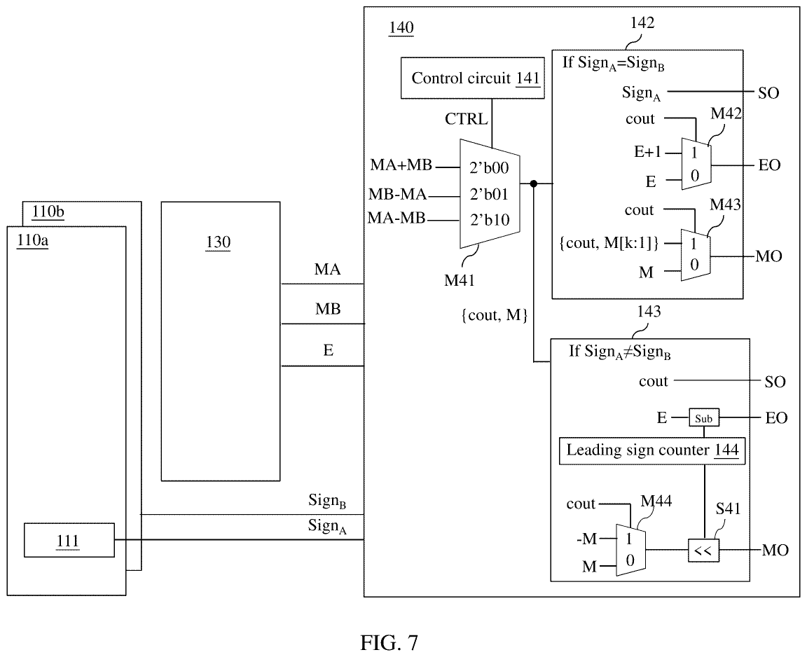

Reference is now made to FIG. 7. FIG. 7 is a schematic diagram of an example of the input processing circuit 110, the exponent circuit 130 and the mantissa circuit 140 of the data processing circuit 100 in FIG. 3, in accordance with various embodiments of the present disclosure. With respect to the embodiments of FIGS. 1-6, like elements in FIG. 7 are designated with the same reference numbers for ease of understanding.

For illustration, the registers 111 of the processing circuit 110a and 110b are coupled to the mantissa circuit 140 to output the sign Sign_{A} and the sign Sign_{B} to the mantissa circuit 140 respectively. The exponent circuit 130 is coupled to the mantissa circuit 140 to output the mantissas MA, MB and the exponent E to the mantissa circuit 140.

As shown in FIG. 7, the mantissa circuit 140 includes a control circuit 141, a processing circuit 142, a processing circuit 143 and a multiplexer M41. The control circuit 141 is coupled to the multiplexer M41. The multiplexer M41 is coupled to the processing circuits 142 and 143.

The control circuit 141 generates a control signal CTRL to the multiplexer M41. The control circuit 141 determines the control signal CTRL through the following statements: if Sign_{A}==Sign_{B}: CTRL=2′b00; else if Sign_{A}==1′b1: CTRL=2′b01; else if Sign_{B}==1′b1: CTRL=2′b10.

Specifically, when the signs Sign_{A} and Sign_{B} are equal to each other, the control circuit 141 generates a control signal CTRL having two bits zero (2′b00). When the signs Sign_{A} and Sign_{B} are not equal to each other and the sign Sign_{A} is a bit one, the control circuit 141 generates a control signal CTRL having two bits of “01” (2′b01). When the signs Sign_{A} and Sign_{B} are not equal to each other and the sign Sign_{B} is a bit one, the control circuit 141 generates a control signal CTRL having two bits of “10” (2′b10).

The multiplexer M41 is configured to generate data {cout, M} according to the control signal CTRL. Specifically, the mantissa circuit 140 performs addition between the mantissas MA and MB. When the control signal CTRL is 2′b00, the multiplexer M41 selects the addition result between the mantissas MA and MB (MA+MB) as the output (the data {cout, M}) of the multiplexer M41, in which “cout” denotes the MSB of the output and “M” denotes the other bits of the output.

The mantissa circuit 140 performs subtraction between the mantissas MB and MA. When the control signal CTRL is 2′b01, the multiplexer M41 selects the subtraction between the mantissas MB and MA (MB-MA) as the output (the data {cout, M}) of the multiplexer M41.

The mantissa circuit 140 performs subtraction between the mantissas MA and MB. When the control signal CTRL is 2′b10, the multiplexer M41 selects the subtraction between the mantissas MA and MB (MA-MB) as the output (the data {cout, M}) of the multiplexer M41.

The “cout” is configured to indicate a carry of operations between the mantissas MA and MB. Accordingly, the bit length of the data {cout, M} is longer than the mantissas MA and MB by one bit.

The mantissa circuit 140 determines whether the sign Sign_{A} is equal to the sign Sign_{B}. When the sign Sign_{A} is equal to the sign Sign_{B}, the mantissa circuit 140 selects the processing circuit 142 to generate a sign SO, an exponent EO and a mantissa MO as outputs of the mantissa circuit 140. When the sign Sign_{A} is not equal to the sign Sign_{B}, the mantissa circuit 140 selects the processing circuit 143 to generate the sign SO, the exponent EO and the mantissa MO as outputs of the mantissa circuit 140.

The processing circuit 142 includes a multiplexer M42 and a multiplexer M43. When the sign Sign_{A} is equal to the sign Sign_{B}, the processing circuit 143 outputs the sign Sign_{A} as the sign SO. When the “cout” is equal to a bit one, the multiplexer M42 selects the exponent E plus one as the exponent EO. When the “cout” is equal to a bit zero, the multiplexer M42 selects the exponent E as the exponent EO.

When the “cout” is equal to a bit one, the multiplexer M43 selects {cout, M[k:1]} as the mantissa MO. “M[k:1]” corresponds the “k+1”th bit (MSB) to the second bit of the bits “M”. When the “cout” is equal to a bit zero, the multiplexer M43 selects the bits “M” as the mantissa MO.

The processing circuit 143 includes a multiplexer M44, a subtractor Sub, a leading sign counter 144 and a shifter circuit S41. In some embodiments, the leading sign counter 144 receives the data {cout, M} and determines a number of continuous bits of ones or zeros from the MSB side. For example, when there are three continuous bits of ones from the MSB in the data {cout, M}, the leading sign counter 144 outputs a number three.

The subtractor Sub receives the number of bits from the leading sign counter 144. The subtractor subtracts the number from the exponent E to generate the exponent EO.

When the “cout” is equal to a bit one, the multiplexer M44 selects “−M” to output. “−M” corresponds the negative of the number of the “M”. When the “cout” is equal to a bit zero, the multiplexer M44 selects the “M” to output. The shifter circuit S41 shifts the output of the multiplexer M44 to the left (MSB side) by bits with the number outputted from the leading sign counter 144. For example, when the number from the leading sign counter 144 is one, the shifter circuits shifts the “M” or “−M” to the MSB side by one bit. The shifter circuit S41 outputs the shifted “M” or “−M” as the mantissa MO.

Take the input IN_{A} being the FP16 number 16′b0101110100000000 (“320” in decimal form) and the input IN_{B} being the FP8 number 8′b01101100 (“96” in decimal form) for example. As described above, in this case, the sign Sign_{A} and the sign Sign_{B} are both 1′b0. The aligned mantissa MA is 11′b10100000000. The aligned mantissa MB is 11′b00000000001. The exponent E is 8′b00010111.

According to the the sign Sign_{A} and the sign Sign_{B} being equal to each other, the multiplexer M41 selects the addition of aligned mantissas MA and MB as the data {cout, M}, in which the addition of aligned mantissas MA and MB is 12′b010100000001.

According to the the sign Sign_{A} and the sign Sign_{B} being equal to each other, the processing circuit 142 outputs the sign Sign_{A} (1′b0) as the sign SO. According to the carry bit “cout” being 1′b0, the multiplexer M42 outputs the exponent E (8′b00010111) as the exponent EO, and the multiplexer M43 outputs M (11′b10100000001) as the mantissa MO.

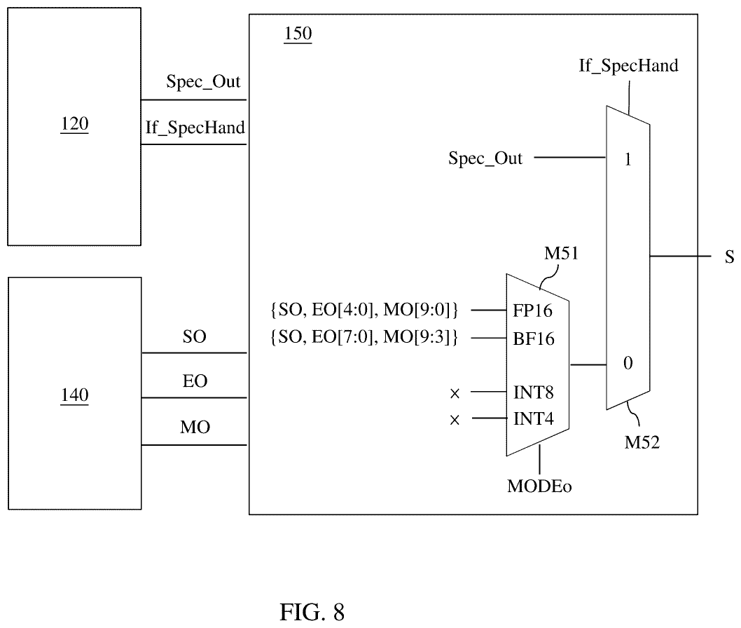

Reference is now made to FIG. 8. FIG. 8 is a schematic diagram of an example of the special case handling circuit 120, the mantissa circuit 140 and the output processing circuit 150 of the data processing circuit 100 in FIG. 3, in accordance with various embodiments of the present disclosure. With respect to the embodiments of FIGS. 1-7, like elements in FIG. 8 are designated with the same reference numbers for ease of understanding.

For illustration, the special case handling circuit 120 is coupled to the output processing circuit to outputs the data Spec_Out and the data If_SpecHand to the output processing circuit 150. The mantissa circuit 140 is coupled to the output processing circuit 150 to outputs the sign SO, the exponent EO and the mantissa MO to the output processing circuit 150.

As shown in FIG. 8, the output processing circuit 150 includes a multiplexer M51 and a multiplexer M52. The multiplexer M51 generates an output according to data MODE_{O}. The data MODE_{O} is determined according to the data MODE_{A} and MODE_{B}. The data MODE_{O} corresponds to the datatype of the sum S. The following table 1 shows the input datatype (corresponding to the data MODE_{A} and MODE_{B}) and the output datatype (corresponding to the data MODE_{O}) of the data processing circuit 100.

TABLE 1

| input datatypes | output datatype |
|---|---|
| INT4 + INT4 | INT4 |
| INT8 + INT8 | INT8 |
| FP8 + FP8 | FP16 |
| FP8 + FP16 | FP16 |
| FP16 + FP16 | FP16 |
| FP8 + BF16 | BF16 |
| BF16 + BF16 | BF16 |

As shown in Table 1, when the data MODE_{A} and MODE_{B} are INT4, the data MODE_{O} is INT4. When the data MODE_{A} and MODE_{B} are INT8, the data MODE_{O} is INT8. When the data MODE_{A} and MODE_{B} are FP8, the data MODE_{O} is FP16. When the data MODE_{A} and MODE_{B} are FP8 and FP16 (or FP16 and FP8), the data MODE_{O} is FP16. When the data MODE_{A} and MODER are FP16 the data MODE_{O} is FP16. When the data MODE_{A} and MODER are FP8 and BF16 (or BF16 and FP8), the data MODE_{O} is BF16. When the data MODE_{A} and MODE_{B} are BF16 the data MODE_{O} is BF16.

When the data MODE_{O} is FP16, the multiplexer M51 selects data {SO, EO[4:0], MO[9:0]} to output. The data {SO, EO[4:0], MO[9:0]} denotes the concatenation of the sign SO, the first bit to the fifth bit of the exponent EO and the first bit to the tenth bit of the mantissa MO. The sign SO is at the MSB side and the bits MO[9:0] is at the LSB side of the data {SO, EO[4:0], MO[9:0]}.

When the data MODE_{O} is BF16, the multiplexer M51 selects data {SO, EO[7:0], MO[9:3]} to output. The data {SO, EO[7:0], MO[9:3]} denotes the concatenation of the sign SO, the first bit to the eighth bit of the exponent EO and the fourth bit to the tenth bit of the mantissa MO. The sign SO is at the MSB side and the bits MO[9:3] is at the LSB side of the data {SO, EO[7:0], MO[9:3]}.

When the data MODE_{O} is INT4 or INT8, the output of the multiplexer M51 is ineffective to the sum S. Therefore, the inputs of the multiplexer M51 corresponding to the data MODE_{O} of INT4 and INT8 are annotated as “x”. In some embodiments, when the data MODE_{O} is INT4 or INT8, the output of the multiplexer M41 is zero.

The multiplexer M52 generates the sum S according to the data If_SpecHand. When the data If_SpecHand is a bit one, the multiplexer M52 selects the data Spec_Out as the sum S. When the data If_SpecHand is a bit zero, the multiplexer M52 selects the output from the multiplexer M51 as the sum S.

Take the input IN_{A} being the FP16 number 16′b0101110100000000 (“320” in decimal form) and the input IN_{B} being the FP8 number 8′b01101100 (“96” in decimal form) for example. As described above, in this case, the sign SO is 1′b0, the exponent EO is 8′b00010111, the mantissa MO is 11′b10100000001, and the data If_SpecHand is 1′b0.

According to the data MODE_{A} and MODE_{B} are FP16 and FP8 respectively, the data MODE_{O} is FP16. According to the data MODE_{O} being FP16, the multiplexer M51 outputs the data {SO, EO[4:0], MO[9:0]} which is 16′b0101110100000001 in this case.

According to the data If_SpecHand being 1′b0, the multiplexer M52 outputs the data {SO, EO[4:0], MO[9:0]} (16′b0101110100000001) from the multiplexer M51 as the sum S.

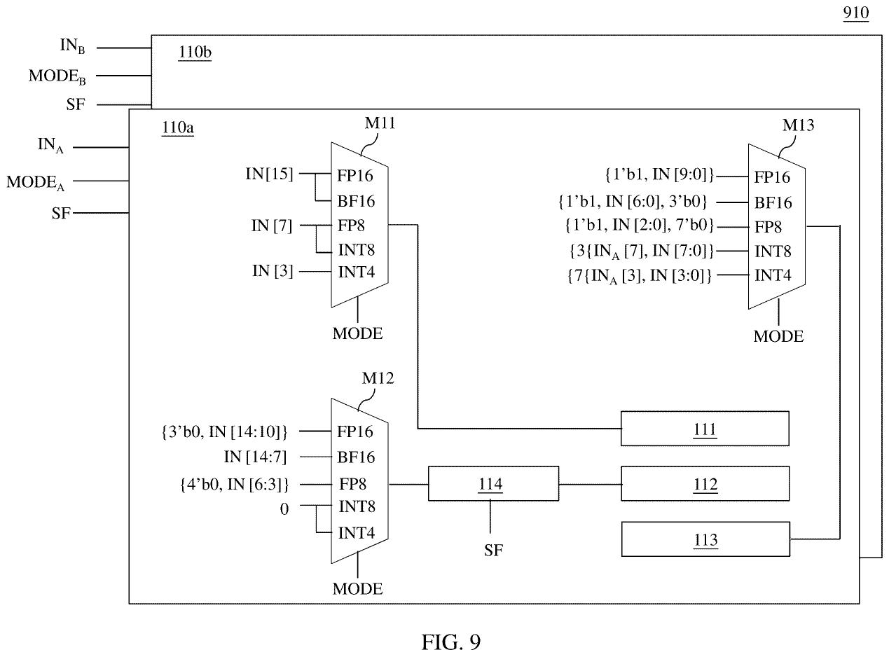

Reference is now made to FIG. 9. FIG. 9 is a schematic diagram of a input processing circuit 910 configured with respect to the input processing circuit 110 in FIG. 4, in accordance with various embodiments of the present disclosure. With respect to the embodiments of FIGS. 1-8, like elements in FIG. 9 are designated with the same reference numbers for ease of understanding.

In some embodiments, the data processing circuit 100 includes the input processing circuit 910 instead of the input processing circuit 110. Compared with the input processing circuit 110, the input processing circuit 910 further includes a exponent align circuit 114. The exponent align circuit 114 is configured to convert an input IN from FP8 to FP16 or BF16 with scaling factor considered. For example, the exponent align circuit 114 receives a scaling factor SF of the input IN to generate a corresponding unscaled exponent in FP16. The exponent align circuit 114 convert the input IN from FP8 to FP16 according to the function: Exp_{FP8}−Bias_{FP8}+Bias_{FP16}+log₂(SF)=Exp_{FP16}. Specifically, when the data mode is FP8, the multiplexer M12 outputs an exponent Exp_{FP8}. The exponent align circuit 114 subtracts a bias Bias_{FP8} from the exponent Exp_{FP8} to generate a first result. The bias Bias_{FP8} is a bias of FP8. In some embodiments, the value of the bias Bias_{FP8} is seven.

Then, the exponent align circuit 114 adds a bias Bias_{FP16} to the first result to generate a second result. The bias Bias_{FP16} is a bias of FP16. In some embodiments, the value of the bias Bias_{FP16} is fifteen.

Then, the exponent align circuit 114 adds the base two logarithm of the scaling factor SF to the second result to generate the exponent Exp₁₆. The exponent Exp₁₆ is the exponent in FP16 corresponding to the unscaled exponent Exp_{FP8}. In some embodiments, the scale factor SF is selected from 2ⁿ, “n” being an integer.

The register 112 stores the exponent Exp₁₆ from the exponent align circuit 114.

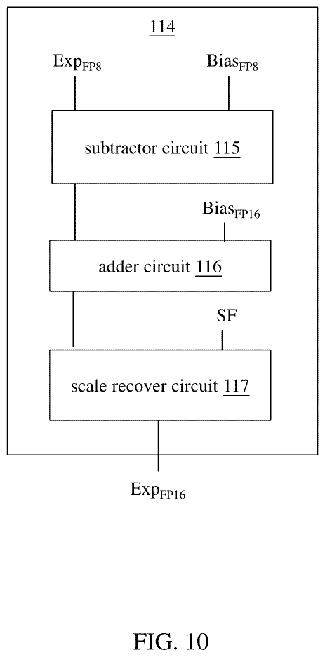

Reference is now made to FIG. 10. FIG. 10 is a schematic diagram of an example of the exponent align circuit 114 of the input processing circuit 910 in FIG. 9, in accordance with various embodiments of the present disclosure. With respect to the embodiments of FIGS. 1-9, like elements in FIG. 10 are designated with the same reference numbers for ease of understanding.

For illustration, the exponent align circuit 114 includes a subtractor circuit 115, an adder circuit 116 and a scale recover circuit 117. The subtractor circuit 115 is coupled to the adder circuit 116. The adder circuit 116 is coupled to the scale recover circuit 117.

The subtractor circuit 115 subtracts the bias Bias_{FP8} from the exponent Exp_{FP8}. The adder circuit 116 adds the Bias_{FP16} to the output of the subtractor circuit 115. In some embodiments, the subtractor circuit 115 may be a subtractor. The adder circuit 116 may be an adder.

The scale recover circuit 117 ganerates the base two logarithm of the scaling factor SF and adds the logarithm result to the output of the adder circuit 116 to generate the unscaled exponent Exp₁₆. In some embodiments, The base two logarithm of the scaling factor SF may be precomputed so that only addition or subtraction is required in circuit 117, allowing for reduced hardware complexity.

In some embodiments, the input processing circuit 910 and the exponent align circuit 114 are not limited to the conversion between FP8 and FP16. The input processing circuit 910 and the exponent align circuit 114 support any datatype conversion (e.g., FP8 to BF16) with additional scaling factor considered for the exponents.

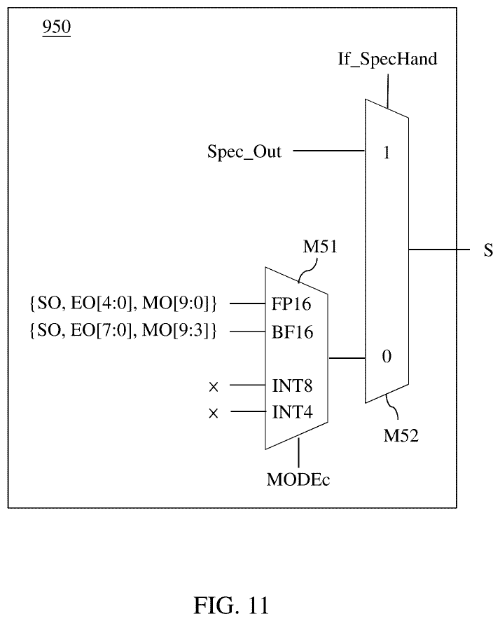

Reference is now made to FIG. 11. FIG. 11 is a schematic diagram of an output processing circuit 950 configured with respect to the output processing circuit 150 in FIG. 8, in accordance with various embodiments of the present disclosure. With respect to the embodiments of FIGS. 1-10, like elements in FIG. 11 are designated with the same reference numbers for ease of understanding.

The difference between the output processing circuit 150 and the output processing circuit 950 is that the multiplexer M51 of the output processing circuit 950 generates the output according to data MODE_{c}. The data MODE_{c} is independent from the data MODE_{A} and MODE_{B}. The data MODE_{c} is according to the datatype of conversion result of the exponent align circuit 114. For example, the data MODE_{c} corresponding to BF16 when the conversion is from FP8 to BF16.

In some embodiment, the data processing circuit 100 includes the input processing circuit 910 and the output processing circuit 950 instead of the input processing circuit 110 and the output processing circuit 150 for datatype conversion.

The configurations of FIGS. 1-11 are given for illustrative purposes. Various implements are within the contemplated scope of the present disclosure. For example, in some embodiments, the output processing circuit 150 is coupled to the data MODE_{A} and MODE_{B} to generate the data MODE_{O}. In some embodiments, the mantissa circuit 140 further includes a multiplexer to select among outputs of the processing circuit 142 and the processing circuit 143 to be the sign SO, exponent EO and the mantissa MO.

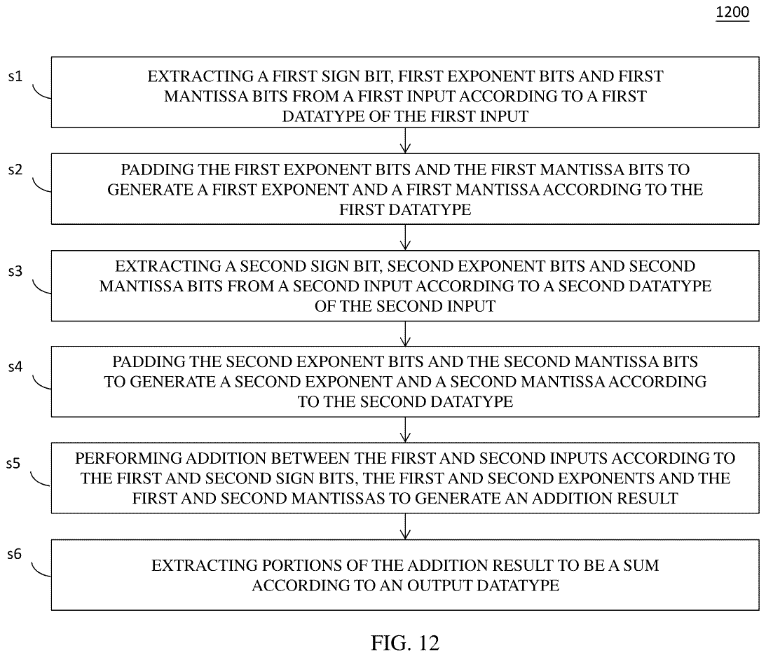

Reference is now made to FIG. 12. FIG. 12 is a flowchart diagram of a method 1200 for operating the system 10A, 10B and the data processing circuit 100 as shown in FIGS. 1-11, in accordance with some embodiments of the present disclosure. It is understood that additional operations can be provided before, during, and after the operations shown by FIG. 12, and some of the operations described below can be replaced or eliminated, for additional embodiments of the method. The order of the operations may be interchangeable. Throughout the various views and illustrative embodiments, like reference numbers are used to designate like elements. The method 1200 includes operations s1-s6 that are described below with reference to the system 10A, 10B and the data processing circuit 100 as shown in FIGS. 1-11.

In step s1, the processing circuit 110a extracts a first sign bit, first exponent bits and first mantissa bits from a first input according to a first datatype of the first input. For example, the processing circuit 110a extracts the data IN[7], the data IN[6:3] and the data IN[2:0] from the input IN when the datatype of the input IN is FP8.

In step s2, the processing circuit 110a pads the first exponent bits and the first mantissa bits to generate a first exponent and a first mantissa according to the first datatype. For example, the processing circuit 110a pads the data IN[6:3] by four bits of zeros from the MSB side when the data MODE is FP8.

In step s3, the processing circuit 110b extracts a second sign bit, second exponent bits and second mantissa bits from a second input according to a second datatype of the second input in a manner similar to the step s1.

In step s4, the processing circuit 110b pads the second exponent bits and the second mantissa bits to generate a second exponent and a second mantissa according to the second datatype in a manner similar to the step s2.

In step s5, the exponent circuit 130 and the mantissa circuit 140 cooperate to perform an addition between the first and second inputs according to the first and second sign bits, the first and second exponents and the first and second mantissas to generate an addition result (e.g., a result including the sign SO, the exponent EO and the mantissa MO).

In step s6, the output processing circuit 150 extracts portions of the addition result to be the sum S according to an output datatype. For example, the output processing circuit 150 extracts data {SO, EO[4:0], MO[9:0]} from the addition result {SO, EO, MO} to be the sum S when the data MODE_{O} is FP8.

In some embodiments, the exponent circuit 130 compares the first exponent and the second to generate a greater exponent (the exponent E). The exponent circuit 130 aligns the first and second mantissas according to the comparison to generate a first aligned mantissa (the mantissa MA) and a second aligned mantissa (the mantissa MB) respectively.

In some embodiments, the mantissa circuit 140 performs an addition or a subtraction between the first and second aligned mantissas according to the first and second sign bits to generate the addition result. For example, when the first and second sign bits are equal to each other, the mantissa circuit 140 performs an addition between the first and second aligned mantissa to generate the addition result.

In some embodiments, the input processing circuit 910 pads the first exponent bits to generated a scaled exponent when the first datatype is a 8-bit floating point. The exponent align circuit 114 performs an recover operation to the scaled exponent according to the Bias_{FP8}, the Bias_{FP16}, and the scaling factor SF to generate a 16-bit floating point exponent as the first exponent.

In some embodiments, the special case handling circuit 120 determines whether the first and second inputs belong to a special case (e.g., being NaN). The multiplexer M21 selects from the NaN, +INF, the first input, the second input, a value of zero and the first mantissa plus the second mantissa to be the sum S.

As described above, the present disclosure provides an AI acceleration system, data processing circuit and method. The design of the data processing circuit support hardware reuse for multiple datatypes (e.g., INT4, INT8, FP8, FP16 and BF16). Such design of sharing hardware helps improve area performance. Compared with some approach, the hardware haring design reduces the area usage by about 26.7 percent. In addition, an addition result between FP8 inputs can be outputted as a FP16 sum for better accumulation precision.

In some embodiments, a system is provided. The system comprises an artificial intelligence accelerator circuit and a data processing circuit. The artificial intelligence accelerator circuit generates multiple results of a machine learning model, wherein the results have different datatypes. The data processing circuit receives two of the results as a first input and a second input and performs an addition between the first and second inputs to generate a sum. The data processing circuit comprises an input processing circuit, an exponent circuit, a mantissa circuit and an output processing circuit. The input processing circuit comprises first and second processing circuits. The first processing circuit extracts a first sign, a first mantissa and a first exponent from the first input and pad the first mantissa and the first exponent to have first and second bit lengths respectively. The second processing circuit generates a second sign, a second mantissa and a second exponent according to the second input. The exponent circuit performs a mantissa alignment to the first and second mantissa according to a comparison between the first and second exponents to generate first and second aligned mantissas and a maximum exponent. The mantissa circuit performs an addition or a subtraction between the first and second aligned mantissas to generate a third sign, a third exponent and a third mantissa according to the first and second signs and the maximum exponent. The output processing circuit comprises a first multiplexer configured to select portions of the third sign, the third exponent and the third mantissa to generate the sum.

In some embodiments, a circuit for data processing is provided. The circuit comprises first and second processing circuits, an exponent circuit, a mantissa circuit and an output processing circuit. The first processing circuit comprises first to third multiplexers configured to generate a first sign, a first exponent, a first mantissa respectively according to a first datatype of a first input. The second processing circuit generates a second sign, a second mantissa and a second exponent according to according to a second datatype of a second input. The exponent circuit performs a mantissa alignment to the first and second mantissa according to a comparison between the first and second exponents to generate first and second aligned mantissas and a maximum exponent. The mantissa circuit configured to generate an addition result of the first input and the second input according to the first and second signs, the first and second aligned mantissas and the maximum exponent. The output processing circuit extracts bits from the addition result according to the third datatype to generate a sum that is in the third datatype.

In some embodiments, a method for data processing is provided. The method comprises: extracting a first sign bit, first exponent bits and first mantissa bits from a first input according to a first datatype of the first input; padding the first exponent bits and the first mantissa bits to generate a first exponent and a first mantissa according to the first datatype; extracting a second sign bit, second exponent bits and second mantissa bits from a second input according to a second datatype of the second input; padding the second exponent bits and the second mantissa bits to generate a second exponent and a second mantissa according to the second datatype; performing an addition between the first and second inputs according to the first and second sign bits, the first and second exponents and the first and second mantissas to generate an addition result; and extracting portions of the addition result to be a sum according to an output datatype.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A system, comprising:
an artificial intelligence accelerator circuit configured to generate a plurality of results of a machine learning model, wherein the results have different datatypes; and
a data processing circuit configured to receive two of the results as a first input and a second input and perform an addition between the first and second inputs to generate a sum,
wherein the data processing circuit comprises:
an input processing circuit comprises:
a first processing circuit configured to extract a first sign, a first mantissa and a first exponent from the first input and pad the first mantissa and the first exponent to have first and second bit lengths respectively; and
a second processing circuit configured to generate a second sign, a second mantissa and a second exponent according to the second input;
an exponent circuit configured to perform a mantissa alignment to the first and second mantissa according to a comparison between the first and second exponents to generate first and second aligned mantissas and a maximum exponent;
a mantissa circuit configured to perform an addition or a subtraction between the first and second aligned mantissas to generate a third sign, a third exponent and a third mantissa according to the first and second signs and the maximum exponent; and
an output processing circuit comprising a first multiplexer configured to select portions of the third sign, the third exponent and the third mantissa to generate the sum.

2. The system of claim 1, wherein the data processing circuit further comprises a special case handling circuit coupled to the input processing circuit, wherein the special case handling circuit comprises:
a mode circuit configured to generate special mode data according to the first and second inputs;
a second multiplexer configured to select among a plurality values to output according to the special mode data; and
an OR circuit configured to perform OR operations to the special mode data to generate first data, wherein the first data indicates whether the first and second inputs belong to a special case.

3. The system of claim 2, wherein the output processing circuit further comprises a third multiplexer configured to select from an output of the first multiplexer and an output of the second multiplexer to be the sum according to the first data.

4. The system of claim 1, wherein the first processing circuit further comprises:
a second multiplexer configured to select a first portion of the first input to be the first sign according to the datatype of the first input;
a third multiplexer configured to select a second portion of the first input to generate the first exponent according to the datatype of the first input; and
a fourth multiplexer configured to select a third portion of the first input to generate the first mantissa according to the datatype of the first input.

5. The system of claim 1, wherein the first processing circuit further comprises:
first to third registers configured to store the first sign, the first exponent and the first mantissa respectively,
wherein the bit length of the second register is equal to the maximum length of the exponents of the different datatypes.

6. The system of claim 1, wherein the exponent circuit further comprises:
a first shifter circuit configured to shift the first mantissa according to the comparison to generate a shifted first mantissa; and
a second shifter circuit configured to shift the second mantissa according to the comparison to generate a shifted second mantissa.

7. The system of claim 6, wherein the exponent circuit further comprises:
a second multiplexer configured to select among the first mantissa and the shifted first mantissa to be the first aligned mantissa according to the comparison;
a third multiplexer configured to select among the second mantissa and the shifted second mantissa to be the second aligned mantissa according to the comparison; and
a fourth multiplexer configured to select among the first exponent and the second exponent to be the maximum exponent according to the comparison.

8. The system of claim 1, wherein the mantissa circuit further comprises:
a control circuit configured to generate a control signal according to the first and second signs; and
a second multiplexer configured to select among an addition between the first and second aligned mantissas, a subtraction of the first aligned mantissa from the second aligned mantissa and a subtraction of the second aligned mantissa from the first aligned mantissa to be a mantissa result.

9. The system of claim 8, wherein the mantissa circuit further comprises:
a third multiplexer configured to select among the maximum exponent and the maximum exponent plus one to be the third exponent according to a carry bit in the mantissa result; and
a fourth multiplexer configured to generate the third mantissa according to the carry bit.

10. The system of claim 8, wherein the mantissa circuit further comprises:
a leading sign counter configured to count a number of continuous bits of ones or zeros in the mantissa result; and
a subtractor configured to subtract the number from the maximum exponent to generate the third exponent.

11. The system of claim 10, wherein the mantissa circuit further comprises:
a third multiplexer configured to generate an output according to the mantissa result; and
a shifter circuit configured to shift the output according to the number.

12. A circuit for data processing, comprising:
a first processing circuit comprising first to third multiplexers configured to generate a first sign, a first exponent, a first mantissa respectively according to a first datatype of a first input;
a second processing circuit configured to generate a second sign, a second mantissa and a second exponent according to according to a second datatype of a second input;
an exponent circuit configured to perform a mantissa alignment to the first and second mantissa according to a comparison between the first and second exponents to generate first and second aligned mantissas and a maximum exponent;
a mantissa circuit configured to generate an addition result of the first input and the second input according to the first and second signs, the first and second aligned mantissas and the maximum exponent; and
an output processing circuit configured to extract bits from the addition result according to a third datatype to generate a sum that is in the third datatype.

13. The circuit of claim 12, wherein the first processing circuit is further configured to extract mantissa bits from the first input and pad the mantissa bits from a least significant side to generate the first mantissa.

14. The circuit of claim 12, further comprising:
a special case handling circuit that comprises:
a fourth multiplexer configured to select among a value of not a number, a positive infinity, a negative infinity, the first input, the second input, a value of zero and the first mantissa plus the second mantissa to be a special case output according to the first and second inputs.

15. The circuit of claim 12, wherein the mantissa circuit further comprises:
a control circuit configured to generate a control signal according to the first and second signs;
a fourth multiplexer configured to select among an addition between the first and second aligned mantissas, a subtraction of the first aligned mantissa from the second aligned mantissa and a subtraction of the second aligned mantissa from the first aligned mantissa to be a mantissa result;
a leading sign counter configured to count a number of continuous bits of ones or zeros in the mantissa result from a most significant side; and
a shifter circuit configured shift an output of a fifth multiplexer according to the number to generate mantissa bits of the addition result.

16. A method for data processing, comprising:
extracting a first sign bit, first exponent bits and first mantissa bits from a first input according to a first datatype of the first input;
padding the first exponent bits and the first mantissa bits to generate a first exponent and a first mantissa according to the first datatype;
extracting a second sign bit, second exponent bits and second mantissa bits from a second input according to a second datatype of the second input;
padding the second exponent bits and the second mantissa bits to generate a second exponent and a second mantissa according to the second datatype;
performing an addition between the first and second inputs according to the first and second sign bits, the first and second exponents and the first and second mantissas to generate an addition result; and
extracting portions of the addition result to be a sum according to an output datatype.

17. The method of claim 16, further comprising:
comparing the first exponent and the second exponent to generate a greater exponent; and
aligning the first and second mantissa according to the comparing to generate a first aligned mantissa and a second aligned mantissa respectively.

18. The method of claim 17, wherein performing the addition comprises:
performing an addition or a subtraction between the first and second aligned mantissas according to the first and second sign bits to generate the addition result.

19. The method of claim 16, wherein padding the first exponent bits comprises:
padding the first exponent bits to generated a scaled exponent when the first datatype is a 8-bit floating point; and
performing an recover operation to the scaled exponent according to a 8-bit floating point bias, a 16-bit floating point bias and a scaling factor to generate a 16-bit floating point exponent as the first exponent.

20. The method of claim 16, further comprising:
determining whether the first and second inputs belong to a special case; and
selecting from a value of not a number, a positive infinity, a negative infinity, the first input, the second input, a value of zero and the first mantissa plus the second mantissa to be the sum.
